(19) United States
(12) Patent Application Publication
(10) Pub. No.: US 2025/0323173 A1
(43) Pub. Date: Oct. 16, 2025

(54) ELECTRONIC DEVICE AND METHOD OF MANUFACTURING THE SAME

(71) Applicant: InnoLux Corporation, Miao-Li County (TW)

(72) Inventors: Hung-Cheng LIN, Miao-Li County (TW); Huan-Chin SHEN, Miao-Li County (TW)

(21) Appl. No.: 19/076,176

(22) Filed: Mar. 11, 2025

Related U.S. Application Data
(60) Provisional application No. 63/632,560, filed on Apr. 11, 2024.

(30) Foreign Application Priority Data
Nov. 11, 2024 (CN) 202411601110.3

(51) Int. Cl. H01L 23/544; H01L 23/31; H01L 23/498

(52) U.S. Cl. CPC H01L 23/544; H01L 23/3128; H01L 23/49816; H01L 2223/54413; H01L 2223/54426

(57) ABSTRACT

An electronic device is provided. The electronic device includes a substrate, a through hole, a circuit structure, at least one electronic unit and at least one mark. The substrate has a first surface and a second surface opposite to the first surface. The through hole penetrates the substrate, and a side wall of the through hole connect the first surface and the second surface. The circuit structure is disposed on the substrate. The at least one electronic unit is disposed on the circuit structure and is electrically connected to the circuit structure. Moreover, the at least one mark is disposed between the first surface and the second surface. A method of manufacturing an electronic device is also provided.

### CROSS REFERENCE TO RELATED APPLICATIONS

This application claims the benefit of China Application No. 202411601110.3, filed Nov. 11, 2024, which claims the benefit of provisional Application No. 63/632,560 filed Apr. 11, 2024, the entirety of which are incorporated by reference herein.

### BACKGROUND

### Technical Field

The present disclosure is related to an electronic device and a method of manufacturing the same, and in particular it is related to an electronic device including a substrate structure with marks, and a method of manufacturing the same.

### Description of the Related Art

Packaging technology can increase the integration density of electronic components (e.g., transistors, diodes, resistors, capacitors, etc.) in a given area, and has been widely used in the production and manufacturing of electronic devices in recent years. As the packaging size of semiconductors becomes smaller, the reliability requirements for chip manufacturing and packaging technology are getting higher.

2.5D or 3D advanced packaging technology using three-dimensional packaging stacks chips and then packages them on the substrate, thereby reducing the area occupied by the chips, reducing the cost and energy consumption associated with driving the chips. Electronic components formed using three-dimensional packaging technology usually have an interposer substrate. An interposer substrate with through holes can provide a shorter signal transmission path, improving the electrical performance of the electronic device or the flexibility of the stacking design.

Generally, there are marks on the surface of the substrate for alignment or recording process-related information. However, the process of forming through holes usually includes an etching process on the substrate, and the etching process may damage these marks, making the marks blurry and difficult to identify. Therefore, developing structures and manufacturing methods of electronic devices that can improve mark maintenance and increase the mark recognition rate is still one of the current research topics in the industry.

### SUMMARY

In accordance with some embodiments of the present disclosure, an electronic device is provided. The electronic device includes a substrate, a through hole, a circuit structure, at least one electronic unit and at least one mark. The substrate has a first surface and a second surface opposite to the first surface. The through hole penetrates the substrate, and a side wall of the through hole connect the first surface and the second surface. The circuit structure is disposed on the substrate. The at least one electronic unit is disposed on the circuit structure and is electrically connected to the circuit structure. Moreover, the at least one mark is disposed between the first surface and the second surface.

In accordance with some other embodiments of the present disclosure, a method of manufacturing an electronic device is provided. The method includes providing a substrate. The substrate has a first surface and a second surface opposite to the first surface. The aforementioned method also includes performing a first modification step on a first region of the substrate, and performing a second modification step on a second region of the substrate. The aforementioned method also includes performing an etching step on the substrate. Furthermore, the first region connects the first surface and the second surface. There is a first distance between the second region and the first surface. There is a second distance between the second region and the second surface. After performing the etching step, a through hole is formed in the first region and at least one mark is formed in the second region.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an electronic device in accordance with some embodiments of the present disclosure;

FIG. 2A and FIG. 2B are partially enlarged cross-sectional diagrams of the area A1 in FIG. 1 in accordance with some embodiments of the present disclosure;

FIG. 3 is a cross-sectional diagram of an electronic device in the intermediate stage of the manufacturing process in accordance with some embodiments of the present disclosure;

FIG. 4 is a top view of an electronic device in accordance with some embodiments of the present disclosure;

FIG. 5 is a cross-sectional diagram of an electronic device in the intermediate stage of the manufacturing process in accordance with some embodiments of the present disclosure;

FIG. 6A and FIG. 6B are cross-sectional diagrams of an electronic device in the intermediate stage of the manufacturing process in accordance with some embodiments of the present disclosure;

FIG. 7 is a cross-sectional diagram of an electronic device in accordance with some embodiments of the present disclosure;

FIG. 8 is a cross-sectional diagram of an electronic device in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, a scanning electron microscope (SEM), an optical microscope (OM), a film thickness profiler (α-step), an ellipsometer or another suitable method may be used to measure the width, thickness or height of each element, or spacing or distance between elements. Specifically, in accordance with some embodiments, a scanning electron microscope may be used to obtain a cross-sectional image including the elements to be measured, and the width, thickness or height of each element, or spacing or distance between elements in the image can be measured.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, an electronic device is provided that includes substrate marks configured in a specific manner, which can overcome problems such as the marks being damaged or blurred during the etching process. This can improve the mark maintenance capability or increase the mark recognition rate, which helps to improve the process yield of electronic devices.

In accordance with the embodiments of the present disclosure, the electronic device can be applied to a power module, a semiconductor packaging device, a display device, a light-emitting device, a backlight device, an antenna device, a touch device, a sensing device, a wearable device, an automotive device, a battery device or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, other suitable materials, or a combination thereof. The electronic device may include electronic components, and the electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro-light-emitting diode (micro LED) or a quantum dot light-emitting diode (QD LED), but it is not limited thereto. In accordance with some embodiments, the electronic device may include a panel and/or a backlight module. The panel may include, for example, a liquid-crystal panel or other self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

Furthermore, in accordance with the embodiments of the present disclosure, the structural design and manufacturing method of the electronic device provided can be applied to, for example, a wafer-level package (WLP) process or a panel-level package (PLP) process, but it is not limited thereto. In accordance with some embodiments, the structural design and manufacturing method of the electronic device provided can be applied to any process that uses marks for reading and identification.

In accordance with the embodiments of the present disclosure, the electronic device may have a packaging structure, and the packaging structure may include a system on package (SoC), a system in package (SiP), a chip on wafer on substrate (CoWoS) package, a system on integrated chip (SoIC) package, an antenna in package (AiP), a co-packaged optics (COP), a micro electro mechanical system (MEMS) or a combination thereof, but it is not limited thereto.

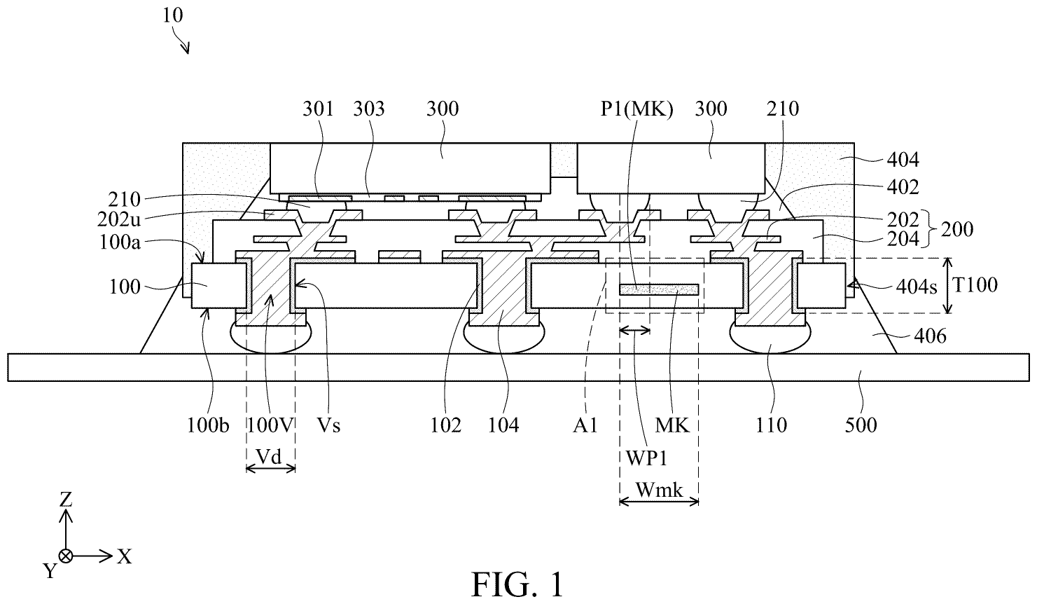

Please refer to FIG. 1, which is a cross-sectional diagram of an electronic device 10 in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below.

As shown in FIG. 1, the electronic device 10 may include a substrate 100, a through hole 100V, a circuit structure 200, at least one electronic unit 300, and at least one mark MK.

The substrate 100 has a first surface 100a and a second surface 100b opposite to the first surface 100a. The through hole 100V penetrates the substrate 100, and a sidewall Vs of the through hole 100V connects the first surface 100a and the second surface 100b.

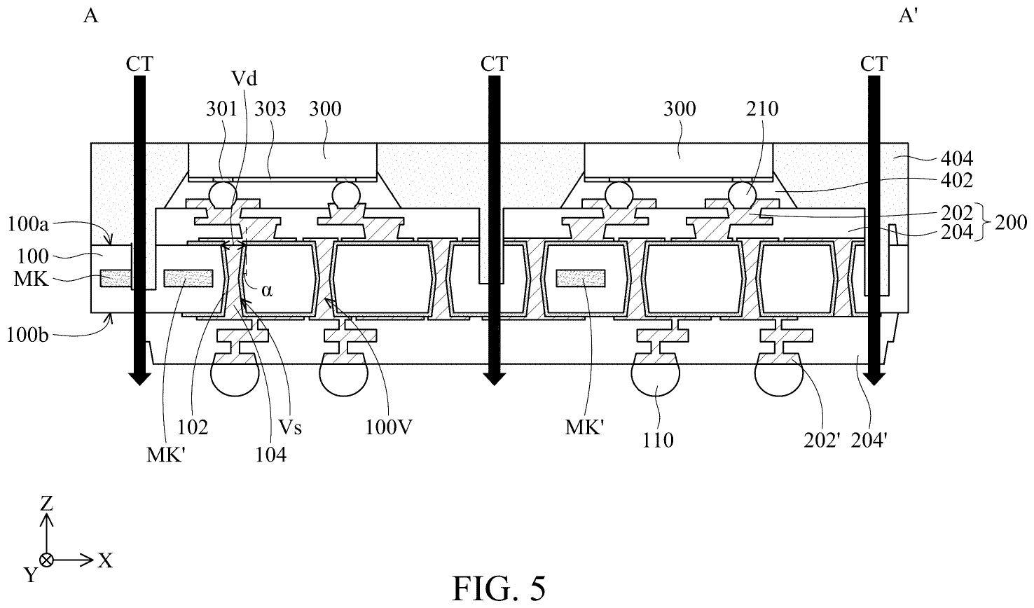

In accordance with some embodiments, the extending direction of the sidewall Vs of the through hole 100V may be substantially parallel to the normal direction of the substrate 100 (for example, the Z direction in the drawing). In accordance with other embodiments, the extending direction of the sidewall Vs of the through hole 100V may be not parallel to the normal direction of the substrate 100 (for example, the Z direction in the drawing). For example, the sidewall Vs of the through hole 100V may be inclined. Referring to FIG. 1 and FIG. 5 at the same time, that is to say, there is an included angle a between the extending direction of the sidewall Vs of the through hole 100V and the normal direction (Z direction) of the substrate 100. The included angle a may be greater than or equal to 0 degrees and less than or equal to 20 degrees, the included angle a may be greater than or equal to 0 degrees and less than or equal to 10 degrees, or the included angle a may be greater than or equal to 0 degrees and less than or equal to 5 degrees. In accordance with some embodiments, the sidewall Vs of the through hole 100V may be inclined outward from the first surface 100a to the second surface 100b (the width of the through hole 100V at the first surface 100a is smaller than the width at the second surface 100b). In accordance with some other embodiments, the sidewall Vs of the through hole 100V may be inclined inward from the first surface 100a to the second surface 100b (the width of the through hole 100V at the first surface 100a is greater than the width at the second surface 100b).

In accordance with some embodiments, the substrate 100 may serve as an interposer for integrating chips or other electronic components for subsequent packaging. In accordance with some embodiments, the substrate 100 may include a silicon substrate, a semiconductor structure substrate, a wafer, a glass substrate, a ceramic substrate, or another suitable substrate, but it is not limited thereto. In accordance with some embodiments, the substrate 100 may be a glass substrate. The substrate 100 may have a thickness T100 in the normal direction of the substrate 100. The thickness T100 of the substrate 100 may be in a range from 50 μm to 1000 μm. In some embodiments, the transmittance of the substrate 100 for light may be at least greater than or equal to 90%, where the light may include white light. The coefficient of thermal expansion (CTE) of the substrate 100 may be greater than or equal to 2 ppm/° C. and less than or equal to 10 ppm/° C. This design can reduce the risk of warpage that may occur when subsequent components are formed on the substrate 100.

In accordance with some embodiments, the substrate 100 may be first subjected to a laser modification process, and then the modified substrate 100 may be removed through one or more photolithography processes and/or etching processes to form the through hole 100V. In accordance with some embodiments, the photolithography process may include providing a laser, photoresist coating (e.g., spin coating), soft bake, hard bake, mask alignment, exposure, post-exposure bake, photoresist development, cleaning and drying, etc., but it is not limited thereto. The etching process may include a dry etching process or a wet etching process, but it is not limited thereto.

Furthermore, the electronic device 10 may include a conductive element 104 disposed in the through hole 100V, and the electronic unit 300 may be electrically connected to the conductive element 104 through the circuit structure 200. In accordance with some embodiments, the electronic device 10 may further include a conductive layer 102 disposed in the through hole 100V, and the conductive layer 102 may be disposed between the substrate 100 and the conductive element 104. In detail, the conductive layer 102 may extend on part of the first surface 100a of the substrate 100, the sidewalls Vs of the through hole 100V, and part of the second surface 100b. The conductive layer 102 can serve as a seed layer to facilitate the formation of the conductive element 104.

In accordance with some embodiments, the conductive layer 102 may include, for example, copper (Cu), titanium (Ti), aluminum (Al), molybdenum (Mo), nickel (Ni), ruthenium (Ru), tantalum (Ta), tungsten (W), nitride, carbide, another suitable conductive material, or a combination thereof, but it is not limited thereto. In accordance with some embodiments, the conductive layer 102 may be a composite layer, for example, including a titanium layer and a copper layer as sub-layers, but it is not limited thereto. In accordance with some embodiments, the conductive layer 102 may be formed by a physical vapor deposition (PVD) process, a chemical deposition process, an atomic layer deposition process, an electroplating process, an electroless plating process, another suitable method, or a combination thereof. In addition, the conductive layer 102 may be patterned through one or more photolithography processes and/or etching processes to define the position of the subsequently formed conductive element 104.

The conductive element 104 may be in contact with the conductive layer 102 and be electrically connected to the conductive layer 102. The conductive element 104 includes a conductive material. In accordance with some embodiments, the material of the conductive element 104 may include copper (Cu), titanium (Ti), aluminum (Al), tungsten (W), silver (Ag), gold (Au), tin (Sn), molybdenum (Mo), chromium (Cr), nickel (Ni), platinum (Pt), alloys of the aforementioned metals, another suitable material or a combination thereof, but it is not limited thereto. In accordance with some embodiments, the conductive element 104 may be formed by a physical vapor deposition process, a chemical deposition process, an atomic layer deposition process, an electroplating process, an electroless plating process, another suitable method, or a combination thereof.

Furthermore, the circuit structure 200 may be disposed on the substrate 100. The circuit structure 200 may be disposed on the first surface 100a and electrically connected to the conductive element 104. In accordance with some embodiments, the circuit structure 200 may be a redistribution layer (RDL), and may include at least one conductive layer 202 (only one layer is shown for convenience of explanation) and at least one insulating layer 204 (only one layer is shown for convenience of explanation). The circuits of the electronic device can be redistributed and/or the circuit fan-out area can be further increased, or different electronic components can be electrically connected to each other through the circuit structure 200. For example, the distance between two adjacent contact pads on the end of the circuit structure 200 close to the electronic unit 300 may be less than or equal to the distance between two adjacent contact pads on the end of the circuit structure 200 far away from the electronic unit 300. Therefore, the circuit structure 200 can adjust the fan-out conditions of circuits, but it is not limited thereto. The redistribution layer can extend a wire to a wider spacing or reroute a wire to another wire with a different spacing, and/or the redistribution layer can serve as a substrate for routing the electrical interface between one connection and another. For example, the pitch of two adjacent contact pads on the end of the redistribution structure that contacts the electronic component may be less than or equal to the pitch of two adjacent contact pads on the end of the redistribution structure away from the electronic component. Therefore, the redistribution structure can adjust the circuit fanout condition or electrically connect the circuit structure/electronic component with the first pitch to the circuit structure/electronic component with the second pitch, but it is not limited thereto. Furthermore, the step of forming the redistribution layer may include providing a stack of at least one conductive layer and at least one dielectric layer, and the method of forming the redistribution layer may include photolithography, etching, surface treatment, laser, electroplating, chemical plating, deposition, atomic layer deposition and other processes. Among them, surface treatment may include roughening or activating the surface of the dielectric layer or the surface of the conductive layer to improve the adhesion ability of the dielectric layer or conductive layer. For example, by increasing the surface roughness, the bonding force with subsequent films can be improved.

The conductive layer 202 may include a conductive material. In accordance with some embodiments, the material of the conductive layer 202 may include copper (Cu), titanium (Ti), aluminum (Al), tungsten (W), silver (Ag), gold (Au), tin (Sn), molybdenum (Mo), chromium (Cr), nickel (Ni), platinum (Pt), tantalum (Ta), alloys of the aforementioned metals, another suitable conductive material, or a combination thereof, but it is not limited thereto. In accordance with some embodiments, the conductive layer 202 may have a multi-layer structure (not shown). In accordance with some embodiments, the conductive material may be formed by an atomic layer deposition process, a physical vapor deposition process, an electroplating process, an electroless plating process, another suitable method, or a combination thereof. Furthermore, the conductive material may be patterned through one or more photolithography processes and/or etching processes to form the conductive layer 202.

Moreover, in accordance with some embodiments, the material of the insulating layer 204 may include a polymer dielectric insulating material, for example, may include polybenzoxazole (PBO), polyimide, benzocyclobutene (BCB), another suitable polymeric dielectric material, or a combination thereof, but it is not limited thereto. In accordance with some other embodiments, the material of the insulating layer 204 may include silicon nitride, silicon oxide, silicon oxynitride, phosphosilicate glass (PSG), borosilicate glass (BSG), boron-doped phosphosilicate glass (BPSG), another suitable dielectric material, or a combination thereof, but it is not limited thereto. In accordance with some embodiments, the insulating layer 204 may be formed by a coating process, a spin coating process, a chemical vapor deposition process, a stacking and lamination process, another suitable method, or a combination thereof.

Furthermore, at least one electronic unit 300 may be disposed on the circuit structure 200 and electrically connected to the circuit structure 200. In accordance with some embodiments, the electronic device 10 may further include a bonding element 210, and the bonding element 210 may be disposed between the electronic unit 300 and the circuit structure 200. Specifically, in accordance with some embodiments, the electronic unit 300 may have a passivation layer 303 and a conductive element 301. The passivation layer 303 may expose the conductive element 301. In the normal direction of the substrate 100 (for example, the Z direction in the drawing), the bonding element 210 may at least partially overlap the conductive element 301 and the passivation layer 303. In accordance with some embodiments, the bonding element 210 may be disposed corresponding to the contact pad 202u of the circuit structure 200 and the conductive element 301 of the electronic unit 300. That is, in the normal direction of the substrate 100 (for example, the Z direction in the drawing), the bonding element 210 may overlap with the contact pad 202u of the circuit structure 200 and the conductive element 301 of the electronic unit 300.

In accordance with some embodiments, the electronic unit 300 may include, for example, a known-good die (KGD), an integrated circuit chip (IC), or a surface mount device (SMD), a diode, a semiconductor structure, a silicon photonic wafer, or another suitable electronic component, but it is not limited thereto.

In accordance with some embodiments, the material of the bonding element 210 may include tin, silver, lead-free tin, copper, nickel, gold, gallium, silver, another suitable material or a combination thereof, but it is not limited thereto. In accordance with some embodiments, the bonding element 210 may be bonded to the contact pad 202u of the circuit structure 200 through a reflow process, a fusion bonding process, a hybrid bonding process, a metal-to-metal bonding process, another suitable method, or a combination thereof, and thereby the electronic unit 300 is bonded to the circuit structure 200.

In addition, in accordance with some embodiments, the electronic device 10 may further include a first buffer layer 402 disposed between the electronic unit 300 and the circuit structure 200. The first buffer layer 402 may be in contact with the bonding element 210 and the electronic unit 300. Furthermore, the first buffer layer 402 may be in contact with the contact pad 202u of the circuit structure 200 and the conductive element 301 of the electronic unit 300. In accordance with some embodiments, the first buffer layer 402 may be partially formed on the side surface of the electronic unit 300. The first buffer layer 402 can reduce the influence of water and oxygen on the electronic unit 300 from the external environment. In accordance with some embodiments, the first buffer layer 402 may have an inclined surface, but it is not limited thereto. In accordance with some embodiments, the first buffer layer 402 may include molding compound, epoxy, another suitable encapsulating material, or a combination thereof, but it is not limited thereto. In accordance with some embodiments, the first buffer layer 402 may be formed by a compression molding process, a transfer molding process, or another suitable method. In accordance with some embodiments, the first buffer layer 402 may be in a liquid or semi-liquid form during a dispensing or molding process and then solidified.

In addition, in accordance with some embodiments, the electronic device 10 may further include an encapsulation layer 404 surrounding the electronic unit 300 and the substrate 100. The encapsulation layer 404 may contact the electronic unit 300, the first buffer layer 402, the circuit structure 200 and the substrate 100. In accordance with some embodiments, the encapsulation layer 404 may cover the side surfaces as well as the top surface of the electronic unit 300. The encapsulation layer 404 can reduce the influence of water and oxygen on the electronic unit 300 from the external environment. In accordance with some embodiments, the encapsulation layer 404 may include molding compound, epoxy resin, another suitable encapsulation material, or a combination thereof, but it is not limited thereto. Furthermore, the material of the encapsulation layer 404 may be the same as or different from the material of the first buffer layer 402. In accordance with some embodiments, the encapsulation layer 404 may be formed by a compression molding process, a transfer molding process, or another suitable method. In accordance with some embodiments, the encapsulation layer 404 may be in a liquid or semi-liquid form during the molding process and then solidified.

In addition, the electronic device 10 may include at least one mark MK disposed between the first surface 100a and the second surface 100b. In other words, the mark MK is disposed inside the substrate 100 and is not disposed on the first surface 100a and the second surface 100b. In particular, the mark MK disposed between the first surface 100a and the second surface 100b can reduce the risk of being damaged or blurred by the etching process.

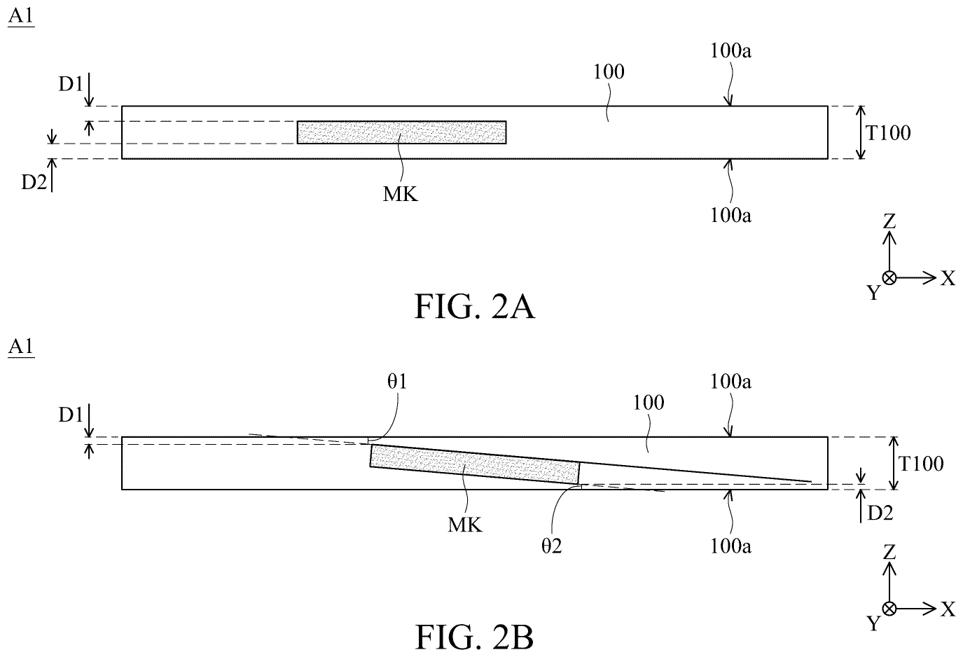

In detail, please refer to FIG. 2A and FIG. 2B, which are partially enlarged cross-sectional diagrams of the area A1 in FIG. 1 in accordance with some embodiments of the present disclosure. As shown in FIG. 2A and FIG. 2B, in the cross-sectional view, there is a first distance D1 between the first surface 100a and the mark MK, and there is a second distance D2 between the second surface 100b and the mark MK. In accordance with some embodiments, the first distance D1 may be greater than or equal to 5 micrometers and less than or equal to half of the thickness T100 of the substrate 100 (i.e. 5 μm≤the first distance D1≤½×thickness T100). In accordance with some embodiments, the second distance D2 may be greater than or equal to 5 micrometers and less than or equal to half of the thickness T100 of the substrate 100 (i.e. 5 μm≤the second distance D2≤½×thickness T100). In accordance with some embodiments, the thickness T100 of the substrate 100 may be greater than 50 micrometers (i.e. the thickness T100>50 μm).

In accordance with the embodiments of the present disclosure, the aforementioned first distance D1 refers to the minimum distance between the mark MK and the first surface 100a of the substrate 100 in the normal direction of the substrate 100 (for example, the Z direction in the drawing). The aforementioned second distance D2 refers to the minimum distance between the mark MK and the second surface 100b of the substrate 100 in the normal direction of the substrate 100. Furthermore, in accordance with the embodiments of the present disclosure, the aforementioned thickness T100 refers to the maximum thickness of the substrate 100 in the normal direction of the substrate 100.

In addition, in accordance with some embodiments, the first distance D1 may be greater than or equal to half of the aperture Vd of the through hole 100V (i.e. the first distance D1≥½×the aperture Vd). In accordance with some embodiments, the second distance D2 may be greater than or equal to half of the aperture Vd of the through hole 100V (i.e. the second distance D2≥½×the aperture Vd).

In accordance with the embodiments of the present disclosure, the aforementioned aperture Vd refers to the aperture diameter of the through hole 100V on the first surface 100a of the substrate 100.

It is worth noting that when the distance between the mark MK and the first surface 100a and the second surface 100b of the substrate 100 is configured in the aforementioned manner, the risk of the mark MK being damaged or blurred by the etching process (for example, the etching process to form the through hole 100V) can be reduced, thereby improving the maintenance ability of the mark MK or increasing the recognition rate of mark MK.

Moreover, as shown in FIG. 2A, in accordance with some embodiments, in the cross-sectional view, the extending direction of the mark MK may be substantially perpendicular to the normal direction of the substrate 100 (for example, the Z direction in the drawing). For example, the extending direction of the mark MK may be substantially parallel to the first surface 100a or the second surface 100b. As shown in FIG. 2B, in accordance with some other embodiments, in the cross-sectional view, the extending direction of the mark MK is not perpendicular to the normal direction of the substrate 100. In other words, the extending direction of the mark MK is not parallel to the first surface 100a or the second surface 100b. There may be a first included angle θ1 between the extending direction of the mark MK and the first surface 100a. There may be a second included angle θ2 between the extending direction of the mark MK and the second surface 100b. In accordance with some embodiments, the first included angle θ1 may be between 0 degrees and 45 degrees. In accordance with some embodiments, the second included angle θ2 may be between 0 degrees and 45 degrees for better identification.

In accordance with some embodiments, the mark MK may include a bar code, a data code, an alignment mark, another suitable mark, or a combination thereof, but it is not limited thereto. The mark MK can be used to record process-related information, such as recording quality data of products in the process, parameters used in the process, etc., providing traceable information, but it is not limited thereto. The mark MK can also be used as an alignment pattern. In accordance with some embodiments, when the mark MK is a barcode or a data code, the information can be read using a barcode reader, a data code reader, etc. in a backlight manner.

In accordance with some embodiments, the mark MK may be formed by a laser modification process. For example, the mark MK may be formed inside the substrate 100 by ultra-fast laser such as Excimer laser, PICO laser or FEMTO laser. The process of forming the mark MK will be described in further detail below.

Please refer to FIG. 1 again. In accordance with some embodiments, in the normal direction of the substrate 100 (for example, the Z direction in the drawing), the bonding element 210 may overlap a first portion P1 of the mark MK, and the width WP1 of the first portion P1 may be smaller than the width Wmk of the mark MK. In other words, in accordance with some embodiments, the mark MK may partially overlap the bonding element 210 in the normal direction of the substrate 100.

In accordance with the embodiments of the present disclosure, the aforementioned width WP1 refers to the maximum width of the first portion P1 of the mark MK in a direction perpendicular to the normal direction of the substrate 100 (for example, the X direction in the drawing); and the aforementioned width Wmk refers to the maximum width of the mark MK in the direction perpendicular to the normal direction of the substrate 100.

It is worth noting that through the above-mentioned configuration of the bonding element 210 and the mark MK, the risk of cracking in the area of the mark MK caused by stress when the component is pressed down can be reduced.

Moreover, in accordance with some embodiments, in the normal direction of the substrate 100 (for example, the Z direction in the drawing), the mark MK does not overlap with the through hole 100V. In accordance with some embodiments, the mark MK may be disposed between the through holes 100V.

As shown in FIG. 1, in accordance with some embodiments, the electronic device 10 may further include a bonding element 110, a second buffer layer 406, and an electronic component 500. The bonding element 110 may be disposed corresponding to the conductive element 104. That is, in the normal direction of the substrate 100 (for example, the Z direction in the drawing), the bonding element 110 may overlap the conductive element 104. One end of the bonding element 110 may be electrically connected to the conductive element 104, and the other end may be electrically connected to the electronic component 500. The second buffer layer 406 may be disposed between the substrate 100 and the electronic component 500. The second buffer layer 406 may be disposed on the second surface 100b of the substrate 100 and contact part of the side surface 404s of the encapsulation layer 404. In accordance with some embodiments, the second buffer layer 406 may have an inclined surface, but it is not limited thereto. Furthermore, the second buffer layer 406 may also be in contact with the conductive element 104 and the bonding element 110. The second buffer layer 406 can reduce the influence of water and oxygen in the external environment on the conductive element 104 and the bonding element 110 and maintain the quality of electrical connection.

In accordance with some embodiments, the material of the bonding element 110 may include tin, silver, lead-free tin, copper, nickel, gold, gallium, silver, another suitable material or a combination thereof, but it is not limited thereto. In accordance with some embodiments, the bonding element 110 may be bonded to the conductive element 104 on the second surface 100b through a reflow process, a fusion bonding process, a hybrid bonding process, a metal-to-metal bonding process, another suitable method, or a combination thereof, and further bonded to the electronic component 500.

In accordance with some embodiments, the second buffer layer 406 may include molding compound, epoxy, another suitable encapsulating material, or a combination thereof, but it is not limited thereto. In accordance with some embodiments, the second buffer layer 406 may be formed by a compression molding process, a transfer molding process, or another suitable method. In accordance with some embodiments, the second buffer layer 406 may be in a liquid or semi-liquid form during a dispensing or molding process and then solidified.

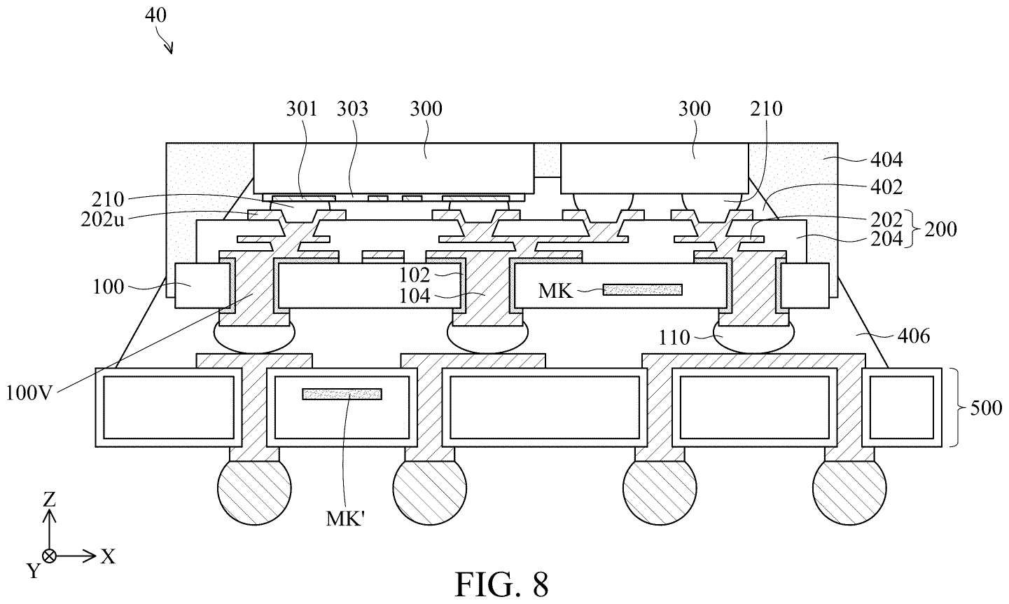

Furthermore, in accordance with some embodiments, the electronic component 500 may include a printed circuit board (PCB), a chip, a control component or another suitable electronic component, but the present disclosure is not limited thereto. In accordance with some embodiments, the electronic component 500 may have a structure similar to the substrate 100, that is, the electronic component 500 may include a glass substrate with through holes, as shown in FIG. 8.

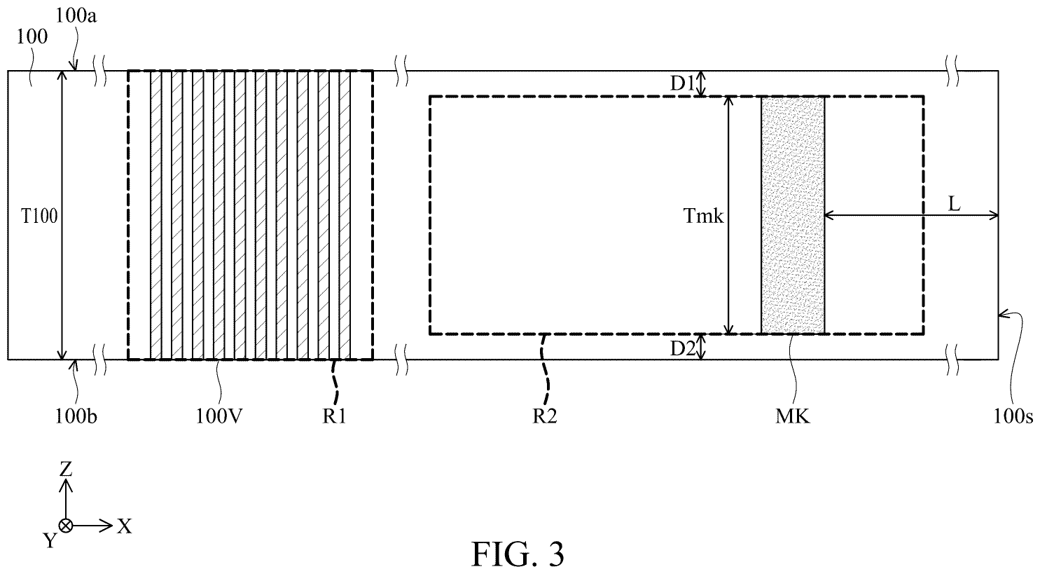

Next, please refer to FIG. 3, which is a cross-sectional diagram of an electronic device in the intermediate stage of the manufacturing process in accordance with some embodiments of the present disclosure. It should be understood that, for clarity of explanation, only the substrate 100 of the electronic device is shown in the drawings. Furthermore, the relevant steps performed on the substrate 100 in the manufacturing method of the electronic device will be described below with reference to FIG. 3. In accordance with some embodiments, additional operation steps may be provided before, during, and/or after the manufacturing method of the electronic device. In accordance with some embodiments, some of the operation steps described may be replaced or omitted, and the order of some of the operation steps described may be interchangeable. In addition, it should be understood that the components or elements that are the same or similar to those mentioned above will be denoted by the same or similar reference numerals, and their materials, functions and manufacturing methods are the same or similar as those mentioned above, and thus will not be repeated herein.

A method of manufacturing an electronic device may include providing a substrate 100. Based on the foregoing, the substrate 100 has a first surface 100a and a second surface 100b opposite to the first surface 100a. Furthermore, the method of manufacturing the electronic device may include performing a first modification step on a first region R1 of the substrate 100 and performing a second modification step on a second region R2 of the substrate 100.

As shown in FIG. 3, in the cross-sectional view, the first region R1 connects the first surface 100a and the second surface 100b, there is a first distance D1 between the second region R2 and the first surface 100a, and there is a second distance D2 between the second region R2 and the second surface 100b. In other words, the first region R1 may cover an area of the complete thickness T100 of the substrate 100, and the second region R2 may cover an area of the thickness smaller than the complete thickness T100 of the substrate 100. For example, the second region R2 may cover the complete thickness T100 of the substrate 100 minus the area separated from the first surface 100a by a first distance D1 and from the second surface 100b by a second distance D2 (that is, the area marked with thickness Tmk in the drawing).

In accordance with some embodiments, the wavelength of the light source used in the first modification step is different from the wavelength of the light source used in the second modification step. In accordance with some embodiments, the wavelength of the light source used in the first modification step for the first region R1 is greater than the wavelength of the light source used in the second modification step for the second region R2. In accordance with some embodiments, the wavelength range of the light source used in the first modification step may be between 400 nanometers and 1400 nanometers, or between 500 nanometers and 800 nanometers. In other words, the light source used in the first modification step may include infrared band or green light band. In accordance with some embodiments, the wavelength range of the light source used in the second modification step may be between 100 nanometers and 400 nanometers. In accordance with some embodiments, the first modification step uses a linear focused (basal beam) laser beam to modify the substrate 100. In accordance with some embodiments, the second modification step uses a single-point focused laser beam (e.g., a Gaussian beam) to modify the substrate 100. In addition, the single-point focused laser beam used in the second modification step may partially overlap or not overlap on the substrate 100.

Moreover, after the aforementioned first modification step and the second modification step, the method of manufacturing the electronic device may further include performing an etching step on the substrate 100. As shown in FIG. 3, after performing the etching step, the through hole 100V is formed in the first region R1 and the mark MK is formed in the second region R2.

Specifically, after the etching step, a portion of the substrate 100 located in the first region R1 is removed to form a through hole 100V, the through hole 100V penetrates the substrate 100, and the through hole 100V connects the first surface 100a and second surface 100b. Furthermore, after the etching step, the portion of the substrate 100 located in the second region R2 is removed to form the mark MK. The mark MK may be formed between the first surface 100a and the second surface 100b. Specifically, there is a first distance D1 between the first surface 100a and the mark MK. The first distance D1 may be greater than or equal to 5 micrometers and less than or equal to half of the thickness T100 of the substrate 100. There is a second distance D2 between the second surface 100b and the mark MK. The second distance D2 may be greater than or equal to 5 micrometers and less than or equal to half of the thickness T100 of the substrate 100. In addition, in accordance with some embodiments, the mark MK in the second region R2 and the sidewall Vs of the substrate 100 may be separated by a distance L, and the distance L may be greater than or equal to half of the aperture Vd of the through hole 100V (i.e. the distance L≥½× the aperture Vd). Through the above design, the risk of substrate being broken can be reduced, but it is not limited thereto.

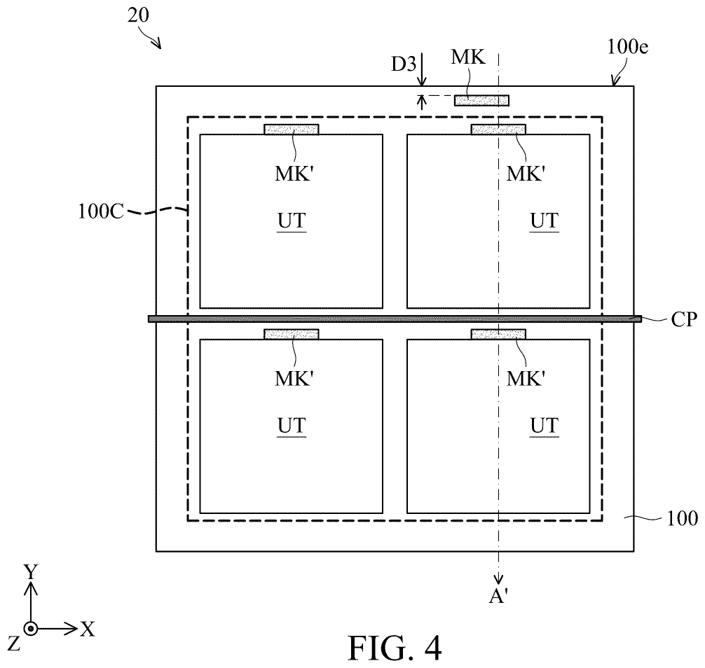

Next, please refer to FIG. 4, which is a top view of an electronic device 20 in accordance with some embodiments of the present disclosure. It should be understood that, for clear explanation, the drawings only schematically illustrate the substrate 100 and some components disposed on the substrate 100.

As shown in FIG. 4, in accordance with some embodiments, the substrate 100 may have an active area 100C, and the active area 100C may include a plurality of electronic unit distribution areas UT. In accordance with some embodiments, the electronic unit distribution areas UT may be arranged in an array, but it is not limited thereto. Furthermore, the electronic unit distribution areas UT may each have a mark MK′. Except for the modified area where the through hole 100V is intended to be formed and the area overlapping the scribe line CP of the electronic device 20, the mark MK′ may be disposed at any suitable position.

In addition, the substrate 100 itself carrying a plurality of electronic unit distribution areas UT may also have a mark MK. The mark MK may be disposed at any suitable position in an edge area of the substrate 100, but can avoid the position where the mechanism clamp is intended to be clamped, thereby reducing the risk of the substrate being broken. In accordance with some embodiments, the edge area of the substrate 100 may be the area between the active area 100C and the edge 100e, and the width of the edge area may be greater than 0 and less than 20 mm. In accordance with some embodiments, in the top view, there is a third distance D3 between the mark MK and the edge 100e of the substrate 100, and the third distance D3 may be greater than half of the aperture Vd of the through hole 100V (i.e. the third distance D3≥½×the aperture Vd).

Please refer to FIG. 5, which is a cross-sectional diagram of an electronic device in the intermediate stage of the manufacturing process in accordance with some embodiments of the present disclosure. Specifically, FIG. 5 is a cross-sectional diagram of the electronic device taken along the section line A-A′ in FIG. 4. The method of manufacturing the electronic device will be described below with reference to FIG. 5. It should be understood that, in accordance with some embodiments, additional operation steps may be provided before, during, and/or after the manufacturing method of the electronic device. In accordance with some embodiments, some of the operation steps described may be replaced or omitted, and the order of some of the operation steps described may be interchangeable.

As shown in FIG. 5, the method of manufacturing the electronic device may include providing the substrate 100, and then performing a modification step (for example, the first modification step and the second modification step as shown in FIG. 3) on the substrate 100. Then, an etching step may be performed on the substrate 100 to form the through hole 100V and the mark MK in the substrate 100. In this embodiment, the sidewalls Vs of the through hole 100V are first inclined inward and then outward from the first surface 100a to the second surface 100b (the width of the through hole 100V between the first surface 100a and the second surface 100b is smaller than the width at the first surface 100a and the second surface 100b).

Furthermore, the conductive layer 102 may be formed in the through hole 100V, and the conductive layer 102 may extend on part of the first surface 100a of the substrate 100, the sidewall Vs of the through hole 100V, and part of the second surface 100b. Afterwards, the conductive element 104 may be formed in the through hole 100V, and the conductive element 104 may contact and be electrically connected to the conductive layer 102. The circuit structure 200 may be formed on the substrate 100. The circuit structure 200 may be formed on the first surface 100a and electrically connected to the conductive element 104. The circuit structure 200 may include at least one conductive layer 202 and at least one insulating layer 204. Then, the electronic unit 300 may be bonded to the circuit structure 200. The bonding element 210 may be formed on the circuit structure 200, and the electronic unit 300 may be electrically connected to the circuit structure 200 through the bonding element 210. Furthermore, the first buffer layer 402 may be formed between the electronic unit 300 and the circuit structure 200, and the first buffer layer 402 may be in contact with the bonding element 210 and the electronic unit 300.

Next, the encapsulation layer 404 may be formed to surround the electronic unit 300 and the substrate 100. The encapsulation layer 404 may be in contact with the electronic unit 300, the first buffer layer 402, the circuit structure 200 and the substrate 100. In addition, at least one conductive layer 202′, at least one insulating layer 204′ and the bonding element 110 may be formed on the second surface 100b of the substrate 100.

In this embodiment, after the packaging structure is completed, a cutting step CT may be performed to separate the electronic units 300 located in different electronic unit distribution areas UT. The cutting step CT may cut the encapsulation layer 404, the circuit structure 200, the conductive layer 102, the substrate 100, the insulating layer 204′, etc. In accordance with some embodiments, the cutting step CT may include a laser cutting process, a knife cutting process, or a combination thereof, but it is not limited thereto.

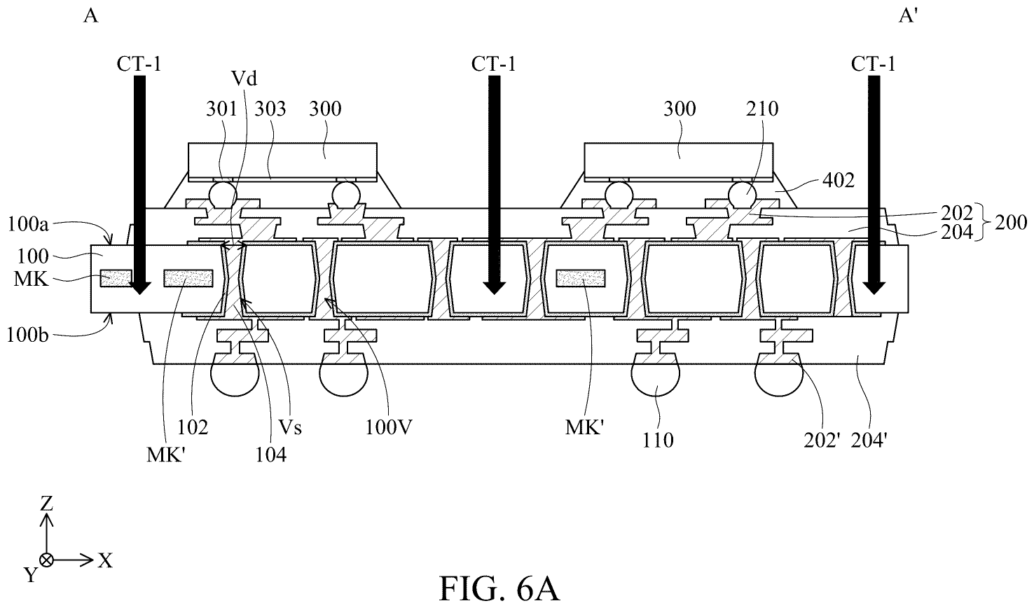

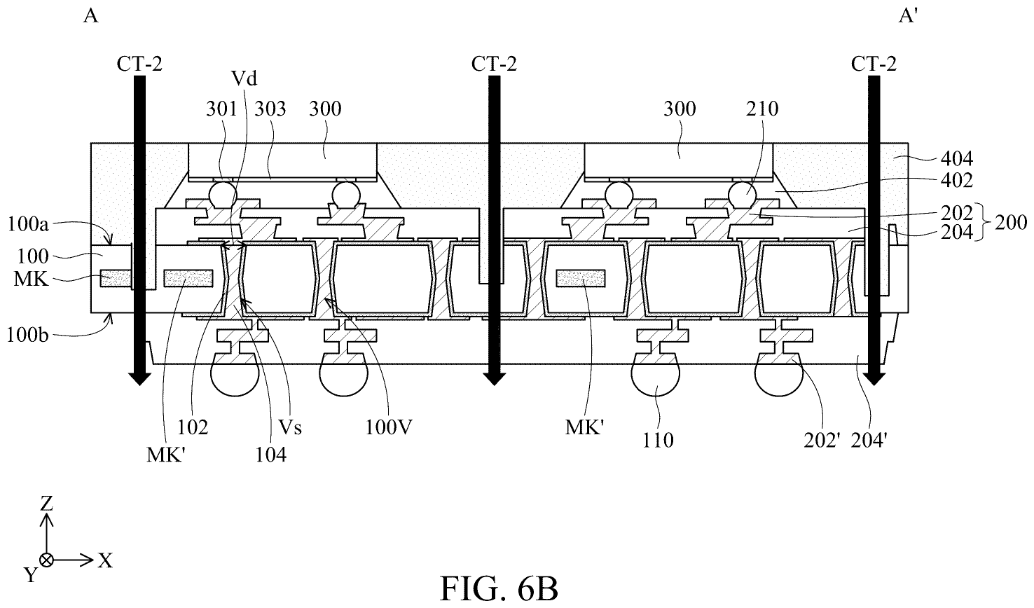

Please refer to FIG. 6A and FIG. 6B, which are cross-sectional diagrams of an electronic device in the intermediate stage of the manufacturing process in accordance with some other embodiments of the present disclosure. Specifically, FIG. 6A and FIG. 6B are cross-sectional diagrams of the electronic device taken along the section line A-A′ in FIG. 4.

As shown in FIG. 6A, the method of manufacturing the electronic device may include providing the substrate 100, and then performing a modification step (for example, the first modification step and the second modification step as shown in FIG. 3) on the substrate 100. Then, an etching step may be performed on the substrate 100 to form the through hole 100V and the mark MK in the substrate 100. In this embodiment, the sidewalls Vs of the through hole 100V are first inclined inward and then outward from the first surface 100a to the second surface 100b (the width of the through hole 100V between the first surface 100a and the second surface 100b is smaller than the width at the first surface 100a and the second surface 100b).

Furthermore, the conductive layer 102 may be formed in the through hole 100V, and the conductive layer 102 may extend on part of the first surface 100a of the substrate 100, the sidewalls Vs of the through hole 100V, and part of the second surface 100b. Afterwards, the conductive element 104 may be formed in the through hole 100V, and the conductive element 104 may contact and be electrically connected to the conductive layer 102. The circuit structure 200 may be formed on the substrate 100. The circuit structure 200 may be formed on the first surface 100a and be electrically connected to the conductive element 104. The circuit structure 200 may include at least one conductive layer 202 and at least one insulating layer 204. Then, the electronic unit 300 may be bonded to the circuit structure 200. In accordance with some embodiments, the bonding element 210 may be formed on the circuit structure 200, and the electronic unit 300 may be electrically connected to the circuit structure 200 through the bonding element 210. Furthermore, the first buffer layer 402 may be formed between the electronic unit 300 and the circuit structure 200, and the first buffer layer 402 may be in contact with the bonding element 210 and the electronic unit 300.

In this embodiment, after the electronic unit 300 is bonded to the circuit structure 200 and the first buffer layer 402 is formed, a first cutting step CT-1 may be performed. The first cutting step CT-1 may cut the circuit structure 200 and the conductive layer 102. Furthermore, the first cutting step CT-1 may further cut to a part of the substrate 100 and form a groove in the substrate 100. In other words, the first cutting step CT-1 does not completely cut the substrate 100, but only forms a groove on the first surface 100a of the substrate 100. In accordance with some embodiments, the first cutting step CT-1 may include a laser cutting process, a knife cutting process, or a combination thereof, but it is not limited thereto.

As shown in FIG. 6B, the encapsulation layer 404 may be formed to surround the electronic unit 300 and the substrate 100. The encapsulation layer 404 may be in contact with the electronic unit 300, the first buffer layer 402, the circuit structure 200, the conductive layer 102 and the substrate 100. Furthermore, the encapsulation layer 404 may also be formed in the groove of the first surface 100a. In addition, at least one conductive layer 202′, at least one insulating layer 204′ and the bonding element 110 may be formed on the second surface 100b of the substrate 100.

In this embodiment, after the packaging structure is completed, a second cutting step CT-2 may be performed to separate the electronic units 300 located in different electronic unit distribution areas UT. The second cutting step CT-2 may cut substantially along the cutting path of the first cutting step CT-1, and the second cutting step CT-2 may cut the encapsulation layer 404, the conductive layer 102, the substrate 100, the insulating layer 204′, etc. In this embodiment, the first cutting step CT-1 may be performed during the formation of the packaging structure (for example, before the encapsulation layer 404 is formed), and after the packaging structure is completed (for example, after the encapsulation layer 404 is formed), the second cutting step CT-2 may be performed. In accordance with some embodiments, the second cutting step CT-2 may include a laser cutting process, a knife cutting process, or a combination thereof, but it is not limited thereto.

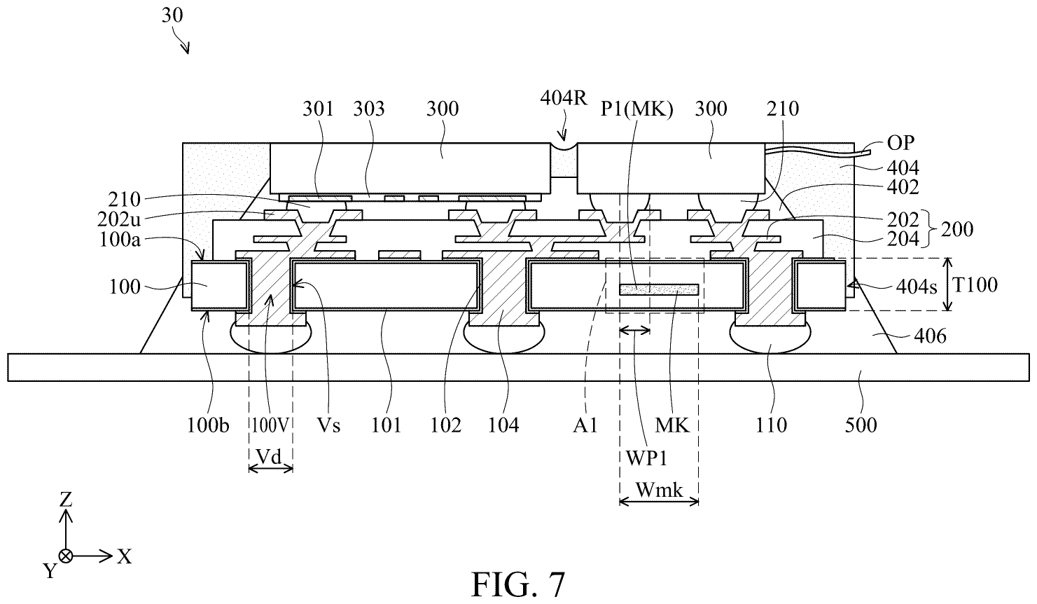

Please refer to FIG. 7, which is a cross-sectional diagram of an electronic device 30 in accordance with some other embodiments of the present disclosure. The electronic device 30 is substantially similar to the electronic device 10 shown in FIG. 1. Compared with the electronic device 10, the electronic device 30 further includes a protective layer 101 disposed between the substrate 100 and the conductive layer 102. The electronic device 30 may further include an optical element OP coupled to the electronic unit 300. Furthermore, the electronic unit 300 and the optical element OP may be regarded as an optical component (for example, a light engine). The electronic unit 300 may include an electrical integrated circuit (EIC), photonic integrated circuit (PIC), or a combination of the two. The electronic unit 300 may further include a base layer with through-silicon vias (TSV), but it is not limited thereto. The electronic device 30 may be applied to a silicon photonic co-packaged optics (CPO) device.

In detail, the protective layer 101 may be disposed on the first surface 100a, the second surface 100b and the sidewalls Vs of the substrate 100, and the protective layer 101 may extend in the through hole 100V. The protective layer 101 can protect the substrate 100, improve the structural strength of the substrate 100, and reduce the risk of damaging the substrate 100 in subsequent processes. The protective layer 101 may include an organic material. In accordance with some embodiments, the material of the protective layer 101 may include polyimide (PI), benzocyclobutene (BCB), epoxy, polyethylene terephthalate (PET), polycarbonate (PC), polyethylene naphthalate (PEN), parylene, another suitable organic material or a combination thereof, but it is not limited thereto. In accordance with some embodiments, the protective layer 101 may be formed by a coating process, a spin coating process, a chemical vapor deposition (CVD) process, an atomic layer deposition (ALD) process, another suitable method, or a combination thereof. The thickness of the protective layer 101 may be, for example, greater than or equal to 0.01 μm and less than or equal to 10 μm (i.e. 0.01 μm≤the thickness of the protective layer 101≤10 μm). For example, when the thickness of the protective layer 101 gradually becomes thinner from the surface to away from surface, the protective layer 101 covering the minimum aperture of the sidewall Vs of the through hole 100V usually has the minimum thickness, but it is not limited thereto. The ratio of the thickness of the protective layer 101 to the aperture of the through hole 100V may, for example, be greater than or equal to 0.02 and less than or equal to 0.2 (i.e. 0.02≤the ratio of the thickness of the protective layer 101 to the aperture of the through hole 100V≤0.2). The aperture or thickness described in the present disclosure is measured along a direction perpendicular to the normal direction of the substrate 100 (for example, the X direction). The toughness of the protective layer 101 may be greater than or equal to 0.1 kilojoules/square meter (kJ/m²) and less than or equal to 100 KJ/m² (i.e. 0.1 kJ/m2≤toughness of the protective layer 101≤100 KJ/m²). Herein, the toughness of the film layer can be obtained by integrating the area under the stress-strain curve, and the stress-strain curve can be obtained by tensile testing of the film layer with a universal testing machine (UTM).

In addition, compared with the electronic device 10, the electronic device 30 further includes a recessed profile 404R disposed on the encapsulation layer 404, and the recessed profile 404R may be located between the electronic units 300.

Please refer to FIG. 8, which is a cross-sectional diagram of an electronic device 40 in accordance with some other embodiments of the present disclosure. The electronic device 40 is substantially similar to the electronic device 10 shown in FIG. 1. Compared with the electronic device 10, the electronic component 500 in the electronic device 40 may be a glass substrate with through holes, which may have a structure similar to the substrate 100, which will not be repeated here. As shown in FIG. 8, in accordance with some embodiments, in the normal direction of the substrate 100, the mark MK′ disposed in the electronic component 500 does not overlap with the mark MK disposed in the substrate 100. In particular, with this configuration, the risk of peeling and cracking of the electronic device structure can be reduced. In accordance with some embodiments, the electronic component 500 may be thicker than the substrate 100. In accordance with some embodiments, the thermal expansion coefficient of the electronic component 500 may be smaller than the thermal expansion coefficient of the substrate 100. Through the above design, the supporting force of the electronic component 500 can be improved.

To summarize the above, in accordance with the embodiments of the present disclosure, the electronic device provided includes substrate marks configured in a specific manner, which can overcome problems such as the marks being damaged or blurred during the etching process. This can improve the mark maintenance capability or increase the mark recognition rate, which helps to improve the process yield of electronic devices.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate having a first surface and a second surface opposite to the first surface;
a through hole penetrating the substrate, wherein a sidewall of the through hole connects the first surface and the second surface;
a circuit structure disposed on the substrate;
at least one electronic unit disposed on the circuit structure and electrically connected to the circuit structure; and
at least one mark disposed between the first surface and the second surface.

2. The electronic device as claimed in claim 1, wherein there is a first distance between the first surface and the at least one mark, and the first distance is greater than or equal to 5 micrometers and less than or equal to half of a thickness of the substrate.

3. The electronic device as claimed in claim 1, wherein there is a second distance between the second surface and the at least one mark, and the second distance is greater than or equal to 5 micrometers and less than or equal to half of a thickness of the substrate.

4. The electronic device as claimed in claim 1, further comprising:
a bonding element disposed between the at least one electronic unit and the circuit structure, wherein along a normal direction of the substrate, the bonding element overlaps a first portion of the at least one mark and a width of the first portion is smaller than a width of the at least one mark.

5. The electronic device as claimed in claim 1, further comprising:
a conductive element disposed in the through hole, wherein the at least one electronic unit is electrically connected to the conductive element through the circuit structure.

6. The electronic device as claimed in claim 1, wherein in a top view, there is a third distance between the at least one mark and an edge of the substrate, and the third distance is greater than half of the size of an aperture of the through hole.

7. The electronic device as claimed in claim 1, wherein the at least one mark does not overlap with the through hole along a normal direction of the substrate.

8. The electronic device as claimed in claim 1, wherein the at least one mark includes a bar code, a data code, an alignment mark, or a combination thereof.

9. The electronic device as claimed in claim 1, wherein in a cross-sectional view, an extending direction of the at least one mark is perpendicular to a normal direction of the substrate.

10. The electronic device as claimed in claim 1, wherein in a cross-sectional view, an extending direction of the at least one mark is not perpendicular to a normal direction of the substrate.

11. The electronic device as claimed in claim 1, further comprising:
an encapsulation layer surrounding the at least one electronic unit and the substrate.

12. The electronic device as claimed in claim 11, further comprising:
a first buffer layer disposed between the electronic unit and the circuit structure; and
a second buffer layer disposed on the second surface of the substrate and contacting part of a side surface of the encapsulation layer.

13. A method of manufacturing an electronic device, comprising:
providing a substrate having a first surface and a second surface opposite to the first surface;
performing a first modification step on a first region of the substrate; and
performing a second modification step on a second region of the substrate;
wherein the first region connects the first surface and the second surface, there is a first distance between the second region and the first surface, and there is a second distance between the second region and the second surface.

14. The method of manufacturing an electronic device as claimed in claim 13, wherein a wavelength of a light source used in the first modification step is different from a wavelength of the light source used in the second modification step.

15. The method of manufacturing an electronic device as claimed in claim 14, wherein a wavelength range of the light source used in the first modification step is between 400 nanometers and 1400 nanometers.

16. The method of manufacturing an electronic device as claimed in claim 14, wherein a wavelength range of the light source used in the second modification step is between 100 nanometers and 400 nanometers.

17. The method of manufacturing an electronic device as claimed in claim 13, further comprising:
performing an etching step on the substrate, wherein after performing the etching step, a through hole is formed in the first region and at least one mark is formed in the second region.

18. The method of manufacturing an electronic device as claimed in claim 17, wherein the at least one mark is formed between the first surface and the second surface.

19. The method of manufacturing an electronic device as claimed in claim 13, wherein the first distance is greater than or equal to 5 micrometers and less than or equal to half of a thickness of the substrate.

20. The method of manufacturing an electronic device as claimed in claim 13, wherein the second distance is greater than or equal to 5 micrometers and less than or equal to half of a thickness of the substrate.
